(19) United States
(12) Patent Application Publication
(10) Pub. No.: US 2007/0176262 A1
(43) Pub. Date: Aug. 2, 2007

(54) Series connection of a diode laser bar

(76) Inventor: Ernest Sirkin, Kendall Park, NJ (US)

Correspondence Address: PROSKAUER ROSE LLP, ONE INTERNATIONAL PLACE 14TH FL, BOSTON, MA, 02110, US

(21) Appl. No.: 11/503,492

(22) Filed: Aug. 11, 2006

Related U.S. Application Data
(60) Provisional application No. 60/707,508, filed on Aug. 11, 2005.

(51) Int. Cl. H01L 29/00

(52) U.S. Cl. 257/546

(57) ABSTRACT

A laser diode array includes a plurality of discrete emitter sections mounted on a substrate. Each discrete emitter section includes a light emitting material having an active region and an inactive region. The substrate provides electrical isolation between adjacent discrete emitter sections. A plurality of wire bonds electrically connects the plurality of discrete emitter sections in a series configuration.

### CROSS-REFERENCE TO RELATED APPLICATIONS

This application claims priority to and the benefit of U.S. provisional patent application Ser. No. 60/707,508 filed Aug. 11, 2005, the entire disclosure of which is herein incorporated by reference.

### FIELD OF THE INVENTION

The invention relates generally to diode laser arrays, and more particularly to a laser diode linear array wired in series and operated under continuous wave conditions.

### BACKGROUND OF THE INVENTION

Lasing action in a semiconductor diode laser is produced by applying a potential difference across a pn-junction. The pn-junction can be doped and contained within a cavity, thus providing the gain medium for the laser. A feedback circuit can be used to control the amount of current supplied to the laser diode. The semiconductor laser diode can be mounted in a laser diode module.

Diode laser power can be scaled up in various ways. For example, laser diodes on laser mounts and copper blocks can be individually fiber coupled and mounted on a base plate. The fibers can be bundled together, and fed to an SMA (SubMiniature version A) or similar connector, which can result in a high power, scalable device. The diode lasers can be cooled via thermoelectric coolers operated by thermistors that monitor diode heat in conjunction with heat sinking across a ventilated area. The bend radius of the fiber and the number of diodes required to obtain a certain output power are the primary drivers of space. Although the devices are reliable since a single under-performing diode, typically, does not result in catastrophic failure for the entire unit, forming devices in this way can be labor intensive and expensive and can consume a relatively large footprint.

Diode laser power also can be scaled up by forming a laser diode bar from a linear array of emitters. For example, a bar can include about twenty emitters spaced apart by about 400 μm to 500 μm. These emitters are wired in parallel, resulting in high current, low voltage devices. An advantage of this approach over the first is a smaller footprint and smaller output beam, e.g., enabled by focusing the emitters into a several hundred micron fiber. In addition, these devices do not require the labor intensive step of mounting and fiber coupling individual diodes. Disadvantages of these devices are that they operate at high current and have demanding cooling requirements, and that these devices can fail as a unit if a single diode begins to degrade.

### SUMMARY OF THE INVENTION

The invention, in various embodiments, features a laser diode array wired in series and operated under continuous wave conditions. In contrast to diode arrays of the prior art, this approach can result in lower operating current and higher operating voltage. The laser diode array can be formed by isolating portions of a light emitting material on substrate, and electrically connecting these portions in a series configuration.

Advantages of the technology include one or more of the following. Catastrophic failure common to laser bars wired in parallel can be prevented, and manufacturing yield can be increased. In addition, less efficient diodes, which typically generate greater heat loads, can be operated in a series linear array fashion. By operating in a low current, continuous wave (CW) condition, heat dissipation requirements are lowered. Because cooling requirements are lower, cost savings can be realized. A laser diode array having a smaller footprint is provided, resulting in a more cost effective system than individually fiber-coupled diodes wired in series. In addition, indium migration between diodes can be prevented by removing portions of the light emitting material and the substrate. Photon emission from adjacent emitters can also be prevented from interfering with one another. This is commonly known as cross-talk between emitters.

In one aspect, the invention features a laser diode array including a plurality of discrete emitter sections mounted on a substrate. Each discrete emitter section includes a light emitting material having an active region and an inactive region. The substrate provides electrical isolation between adjacent discrete emitter sections. A plurality of wire bonds electrically connect the plurality of discrete emitter sections in a series configuration. In one embodiment, each discrete emitter section is physically isolated from an adjacent discrete emitter section.

In another aspect, the invention features a method of forming a laser diode array. A light emitting material having an active region and an inactive region is mounted on a substrate. One or more portions of the inactive region and one or more portions of the substrate are removed to form a plurality of discrete emitter sections in the light emitting material. Each discrete emitter section is electrically isolated from an adjacent discrete emitter section. The plurality of discrete emitter sections are electrically connected in a series configuration to form the laser diode array. Each discrete emitter section can be physically isolated from an adjacent discrete emitter section.

In still another aspect, the invention features a method of preventing indium migration in a series connected, continuous wave laser diode array. The method includes providing a light emitting material having a plurality of active regions spaced on a surface of a substrate and an inactive region encapsulating the active regions on the substrate, and removing one or more portions of the inactive region between adjacent active regions to form a plurality of discrete emitter sections in the light emitting material. One or more portions of the substrate are removed to electrically and physically isolate each discrete emitter section from an adjacent discrete emitter section to prevent indium migration between adjacent discrete emitter sections. The plurality of discrete emitter sections can be electrically connected in a series configuration to form the laser diode array.

In other examples, any of the aspects above or any apparatus or method described herein can include one or more of the following features. In various embodiments, each discrete emitter section can be a laser diode. In one embodiment, a p-type region of a first laser diode is closer to the substrate than a n-type region. Alternatively, a n-type region of a first laser diode is closer to the substrate than a p-type region of the first laser diode.

In various embodiments, a mechanical dicer can be used to remove the one or more portions of the inactive region from the first section and the one or more portions of the substrate from the second section. In some embodiments, adjacent discrete emitter sections can be wire bonded. At least one of the plurality of wire bonds can form an electrical connection between a n-type region of a first discrete emitter section and a portion of the substrate electrically coupled to a p-type region of a second discrete emitter section. At least one of the plurality of wire bonds can form an electrical connection between a p-type region of a first discrete emitter section and a portion of the substrate electrically coupled to a n-type region of a second discrete emitter section.

In some embodiments, the light emitting material is electrically isolated from the substrate. The active region can include a plurality of active layers each disposed in the inactive region of each discrete emitter section. The active region can be adjacent to the substrate, and the inactive region can encapsulate the active region.

In various embodiments, the plurality of discrete emitter sections can include about 15 to about 25 discrete emitter sections. Each discrete emitter section can have a length of between about 400 μm and about 600 μm. Adjacent discrete emitter sections can be separated from each other by between about 0.5 mil and about 2 mils.

In various embodiments, the plurality of discrete emitter sections provides a beam of radiation having one or more wavelengths between about 400 nm and about 2600 nm. In various embodiments, the beam of radiation can have a wavelength of 635 nm, 650 nm, 670 nm, 690 nm, 1208 nm, 1270 nm, 1310 nm, 1450 nm, 1550 nm, 1700 nm, 1930 nm, or 2100 nm. At least one of the plurality of discrete emitter sections can provide a continuous wave beam of laser radiation when an electrical current is applied to the series configuration.

In various embodiments, the light emitting material can be a semiconductor material. Suitable semiconductor materials include InGaAlP, InGaP, InGaAs, InGaN, or InGaAsP. In various embodiments, the substrate can be diamond, ceramic, BeO, alumina, or a gold plated ceramic.

The details of one or more examples are set forth in the accompanying drawings and the description below. Further features, aspects, and advantages of the invention will become apparent from the description, the drawings, and the claims.

### BRIEF DESCRIPTION OF THE DRAWINGS

The advantages of the invention described above, together with further advantages, may be better understood by referring to the following description taken in conjunction with the accompanying drawings. The drawings are not necessarily to scale, emphasis instead generally being placed upon illustrating the principles of the invention.

FIG. 1A shows a sectional view of a light emitting material formed on a substrate.

FIG. 1B shows a plan view of the light emitting material of FIG. 1A formed on a substrate.

FIG. 2A shows a sectional view of a light emitting material diced to form a plurality of discrete emitter sections.

FIG. 2B shows a plan view of the light emitting material of FIG. 2A.

FIG. 3 shows an enlarged sectional view of a light emitting material diced to form a plurality of discrete emitter sections.

FIG. 4A shows a plan view of a laser diode array.

FIG. 4B shows an enlarged perspective view of the laser diode array of FIG. 4A.

FIG. 5 shows a perspective view of a laser diode array including contact portions for making electrical connections.

### DESCRIPTION OF THE INVENTION

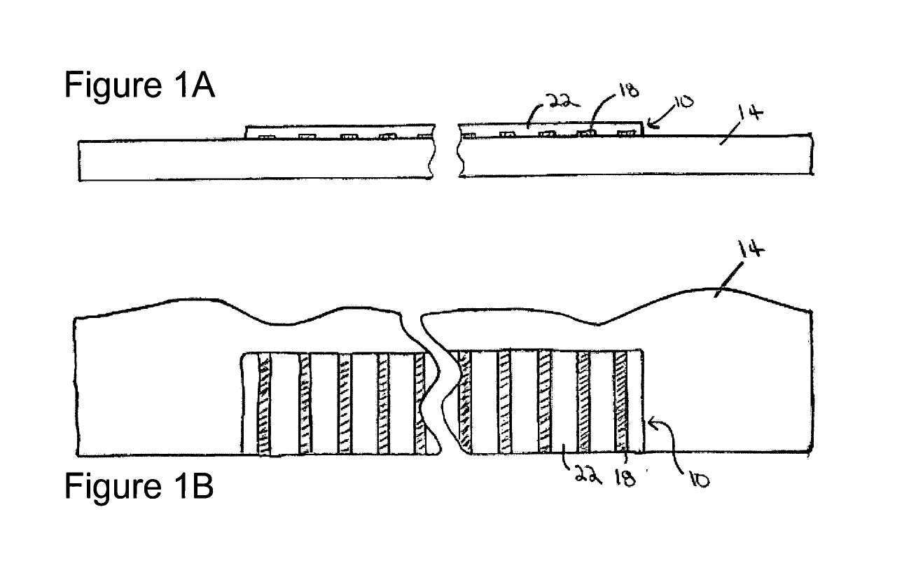

FIGS. 1A and 1B shows a light emitting material 10 formed on a substrate 14. The light emitting material 10 includes one or more active regions 18 and an inactive region 22. In one embodiment, the light emitting material 14 is formed on a wafer and mounted on the substrate 14. The active region(s) 18 can be adjacent the substrate 14, and the inactive region 22 can be formed around the active region(s) 18. In various embodiments, the substrate 14 can be formed from materials such as diamond, ceramic, BeO, alumina, or a gold plated ceramic, although other materials can be used. In an embodiment where the substrate 14 is coated with gold, the edges of the substrate 14 can be free of gold.

In various embodiments, the light emitting material 10 can be soldered to the substrate 14. Suitable solders include, but are not limited to, tin-containing solders such as SnBi, SnPb, and SnPbAg (e.g., Sn62), and gold-containing solders such as AuGe. In various embodiments, the light emitting material 10 can have an anti-reflective coating on a first facet and a high reflective coating on a second facet.

The light emitting material 10 can be formed using a deposition process, lithography, photolithography, an ion implantation process, and/or an epitaxial growth process (e.g., chemical vapor deposition, molecular beam epitaxy, metalorganic vapor phase epitaxy, chemical beam epitaxy, etc.). In one embodiment, a plurality of active regions 18 and an inactive region 22 can be formed on a wafer by photolithography. An advantage of using photolithography is that a homogenous layer of light emitting material can be formed, which can be diced to form a plurality of emitter sections.

In various embodiments, the light emitting material 10 can include a semiconductor material, which can be a doped semiconductor material. In various embodiments, either the active region and/or the inactive region can include one or more of the following materials: InGaAlP, InGaP, InGaAs, InGaN, or InGaAsP. In one embodiment, the active region is InGaAs, and the inactive region is GaAs.

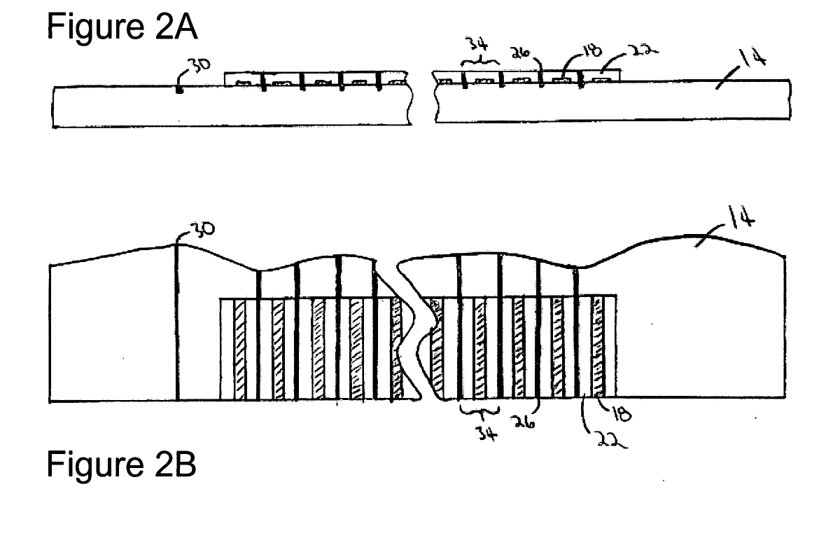

In one embodiment, a laser diode array can be formed by removing one or more portions of the inactive region 22 and one or more portions of the substrate 14 to form a plurality of discrete emitter sections in the light emitting material 10, and electrically connecting the plurality of discrete emitter sections in a series configuration. FIGS. 2A and 2B show a plurality of cuts 26 formed through the inactive region 22 of the light emitting material 10 and into the substrate 14. An additional cut 30 is formed in the substrate 14. The cuts 26 can be removal points or dicing points. The cuts 26 can be positioned between adjacent active regions 18. to form a plurality of discrete emitter sections 34. Each discrete emitter section is electrically and/or physically isolated from an adjacent discrete emitter section. Each discrete emitter section 34 can be a laser diode.

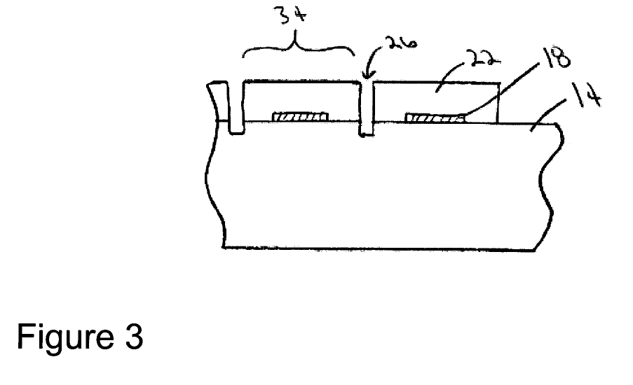

FIG. 3 shows an enlarged section of discrete emitter sections 34 each including an active region 18 and an inactive region 22 formed on a substrate 14 and separated by cuts 26. Indium migration between adjacent discrete emitter sections 34 can be prevented by physically isolating the discrete emitter sections 34.

The light emitting material 10 can include a p-type region and an n-type region. In some embodiments, the light emitting material 10 can be mounted on the substrate 14 with a p-type region of the discrete emitter section 34 or the laser diode closer to the substrate 14 than a n-type region of the discrete emitter section 34 or the laser diode. In certain embodiments, the light emitting material 10 can be mounted on the substrate 14 with a n-type region of the discrete emitter section 34 or the laser diode closer to the substrate 14 than a p-type region of the discrete emitter section 34 or the laser diode.

The cuts 26 and 30 can be formed using an abrasive machining process similar to grinding or a sawing, such as dicing. For example, a mechanical dicer can be used. The mechanical dicer can be a rotating circular abrasive saw blade. The mechanical dicer can cut through the inactive region 22 of the light emitting material 10 and into the substrate 14. The thickness of a dicing blade can be between about 0.5 mil and about 25 mils. In one embodiment, the blade has a kerf that is about 18 μm wide that can form a gap about 25 μm wide between adjacent emitter sections 34. The abrasive material can be diamond particles. For example, the blade can be a metal-bonded diamond blade or a resin-bonded diamond blade. In one embodiment, a wafer dicing system available from Dynatex International (Santa Rosa, Calif.) can be used.

In various embodiments, a light emitting material 10 can be diced into between about 10 and about 25 discrete emitter sections 34, although greater or fewer emitting sections can be used depending on the application. In one embodiment, a device has 10 discrete emitter sections. In one embodiment, a device has 19 discrete emitter sections 34.

In various embodiments, the plurality of discrete emitter sections 34 each can have a length of between about 400 μm and about 600 μm, although longer or shorter sections can be used depending on the application. In one detailed embodiment, each discrete emitter section 34 is about 500 μm in length.

In one embodiment, adjacent discrete emitter sections 34 can be separated by between about 0.5 mil and about 2 mils, although larger or smaller separations can be used depending on the application. In one embodiment, adjacent emitter sections 34 are separated by about 1 mil. In one embodiment, adjacent emitter sections 34 are separated by about 2 mils.

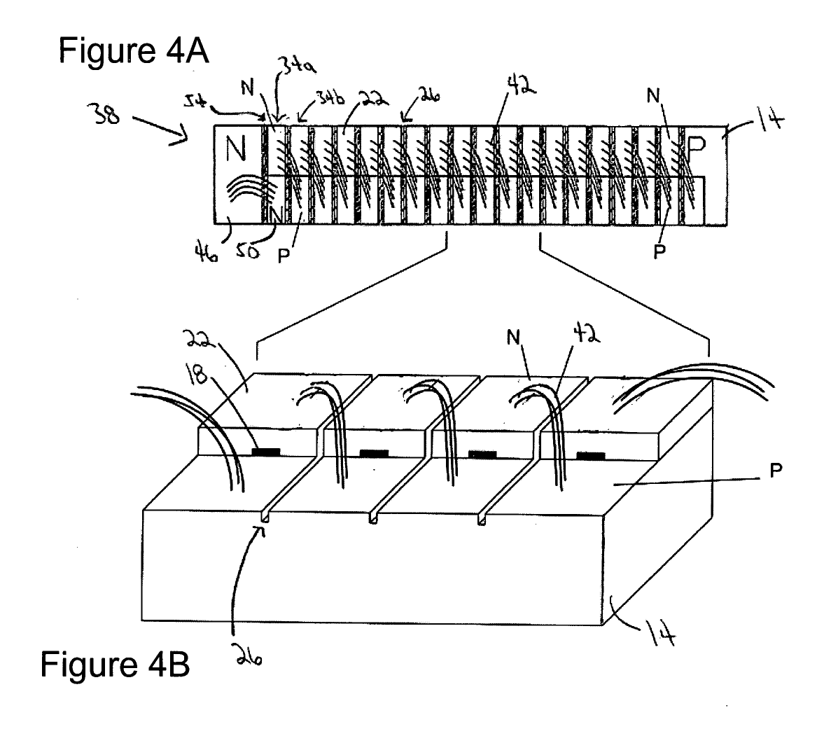

Each discrete emitter section 34 can be electrically connected or wired to the next to form a series connection, which can result in a coplanar (bar) series of laser diodes that are electrically isolated from a mount for the optical device. FIG. 4A shows an exemplary linear array of discrete emitter sections 34 electrically connected in a series configuration to form a laser diode array 38. For example, one or more wires 42 can be used to connect adjacent discrete emitter sections. A wire 42 can be formed from one or more of the following materials—gold, silver, titanium, and copper.

In the embodiment shown in FIG. 4A, a first n-type region 46 is connected to a second n-type region 50 over an isolation cut 54 so that an operator can have a soldering point for connecting to a drive circuit. The remaining connections are formed between an n-type region and an adjacent p-type region. For example, a n-type region of a first discrete emitter section 34a of the light emitting material 10 can be electrically coupled to a p-type region of a second discrete emitter section 34b. The p-type region can be electrically coupled to a portion of the substrate 14, and the n-type region of the first discrete emitter section 34a can be connected to that substrate 14 portion. For example, FIG. 4B shows an enlarged view of four discrete emitter sections 34 of the laser diode array 38 where the wire 42 is bonded to the substrate 14 .

In certain embodiments, a p-type region of a first discrete emitter section 34 of the light emitting material 10 can be electrically coupled to a n-type region of a second discrete emitter section 34. The n-type region can be electrically coupled to a portion of the substrate 10, and the p-type region of the first discrete emitter section 34 can be connected to that substrate 10 portion.

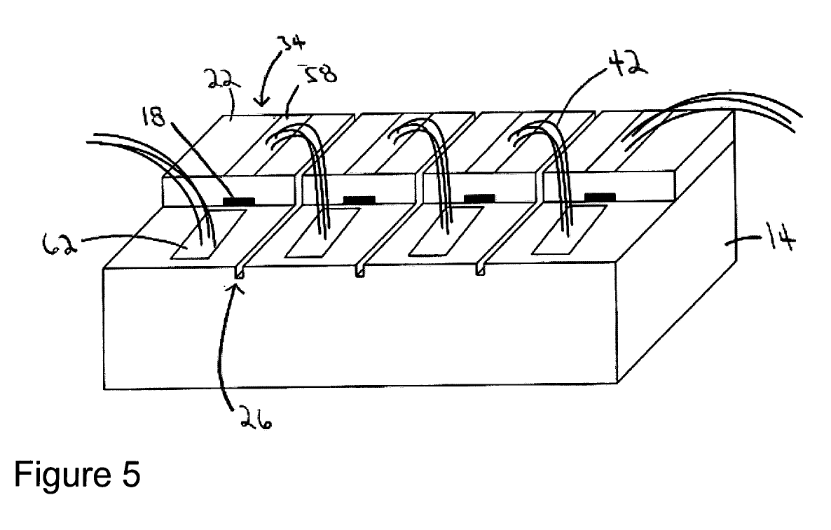

In certain embodiments, a p-type and/or a n-type portion of a discrete emitter section 34 can include an electrical contact on a surface of the discrete emitter section 34 or the substrate 14. FIG. 5 shows a section of a laser diode array including a first electrical contact 58 on the n-type portions and a second electrical contact 62 on a surface of the substrate 14 in electrical communication with the p-type portions of the discrete emitter sections 34. Electrical current can be applied to the first and second electrical contacts 58 and 62 to cause the plurality of discrete emitter sections to generate a continuous wave beam or laser radiation.

In various embodiments, the diode laser array can provide a beam of radiation having one or more wavelengths between about 400 nm and about 2600 nm. The beam of radiation can be provided by a discrete emitter section. In various embodiments, the beam of radiation can have a wavelength of 635 nm, 650 nm, 670 nm, 690 nm, 1,208 nm, 1,270 nm, 1,310 nm, 1,450 nm, 1,550 nm, 1,700 nm, 1,930 nm, or 2,100 nm. The diode laser array and/or one or more of the discrete emitter sections can provide a continuous wave beam of radiation when electrical current is applied.

A laser diode linear array formed using the techniques described above can have an operating current between about 600 mA to about 3 A, although larger or smaller values can result depending on the materials used and the application. A laser diode linear array can have an operating voltage between about 1 V to about 3 V, although larger or smaller values can result depending on the materials used and the application.

A laser diode linear array can have an output power between about 0.1 mW to about 3 W per segment, although larger or smaller values can result depending on the materials used and the application. In one embodiment, the range is between 100 mW to 600 mW. For example, for a laser bar having 19 discrete emitter sections, the total laser power can be about 9.5 W if each emitter section has a power of about 0.5 W.

The invention has been described in terms of particular embodiments. The alternatives described herein are examples for illustration only and not to limit the alternatives in any way. The steps of the invention can be performed in a different order and still achieve desirable results. Other embodiments are within the scope of the following claims.

What is claimed:

1. A method of forming a laser diode array, comprising:
mounting a light emitting material having an active region and an inactive region on a substrate;
removing one or more portions of the inactive region and one or more portions of the substrate to form a plurality of discrete emitter sections in the light emitting material, each discrete emitter section electrically isolated from an adjacent discrete emitter section; and
electrically connecting the plurality of discrete emitter sections in a series configuration to form the laser diode array.

2. The method of claim 1 wherein each discrete emitter section is physically isolated from an adjacent discrete emitter section.

3. The method of claim 1 wherein each discrete emitter section comprises a laser diode.

4. The method of claim 1 wherein removing the one or more portions of the inactive region and the one or more portions of the substrate comprises cutting through a first section of the inactive region and a second section of the substrate using a mechanical dicer to remove the one or more portions of the inactive region from the first section and the one or more portions of the substrate from the second section.

5. The method of claim 1 wherein electrically connecting the plurality of discrete emitter sections comprises wire bonding adjacent discrete emitter sections.

6. The method of claim 3 wherein a p-type region of a first laser diode is closer to the substrate than a n-type region of the first laser diode.

7. The method of claim 3 wherein a n-type region of a first laser diode is closer to the substrate than a p-type region of the first laser diode.

8. The method of claim 1 wherein electrically connecting the plurality of discrete emitter sections comprises forming an electrical connection between a n-type region of a first discrete emitter section and a portion of the substrate electrically coupled to a p-type region of a second discrete emitter section.

9. The method of claim 1 wherein electrically connecting the plurality of discrete emitter sections comprises forming an electrical connection between a p-type region of a first discrete emitter section and a portion of the substrate electrically coupled to a n-type region of a second discrete emitter section.

10. The method of claim 1 wherein applying an electrical current to the series configuration of the plurality of discrete emitter sections provides continuous wave laser radiation.

11. The method of claim 1 wherein the light emitting material comprises a semiconductor material.

12. The method of claim 1 wherein the active region is disposed adjacent to the substrate.

13. A laser diode array comprising:
a plurality of discrete emitter sections each comprising a light emitting material having an active region and an inactive region;
a substrate, wherein the plurality of discrete emitter sections are mounted on the substrate, the substrate providing electrical isolation between adjacent discrete emitter sections; and
a plurality of wire bonds electrically connecting the plurality of discrete emitter sections in a series configuration.

14. The laser diode array of claim 13 wherein each discrete emitter section is physically isolated from an adjacent discrete emitter section.

15. The laser diode array of claim 13 wherein each discrete emitter section comprises a laser diode.

16. The laser diode array of claim 15 wherein a p-type region of a first laser diode is closer to the substrate than a n-type region of the first laser diode.

17. The laser diode array of claim 15 wherein a n-type region of a first laser diode is closer to the substrate than a p-type region of the first laser diode.

18. The laser diode array of claim 13 wherein at least one of the plurality of wire bonds forms an electrical connection between a n-type region of a first discrete emitter section and a portion of the substrate electrically coupled to a p-type region of a second discrete emitter section.

19. The laser diode array of claim 13 wherein at least one of the plurality of wire bonds forms an electrical connection between a p-type region of a first discrete emitter section and a portion of the substrate electrically coupled to a n-type region of a second discrete emitter section.

20. The laser diode array of claim 13 wherein the light emitting material is electrically isolated from the substrate.

21. The laser diode array of claim 13 wherein the active region comprises a plurality of active layers each disposed in the inactive region of each discrete emitter section.

22. The laser diode array of claim 13 wherein the active region is disposed adjacent to the substrate and the inactive region encapsulates the active region.

23. The laser diode array of claim 13 wherein each discrete emitter section has a length of between about 400 μm and about 600 μm.

24. The laser diode array of claim 13 wherein the plurality of discrete emitter sections comprises between about 15 to about 25 discrete emitter sections.

25. The laser diode array of claim 13 wherein adjacent discrete emitter sections are separated from each other by between about 0.5 mil and about 2 mils.

26. The laser diode array of claim 13 wherein at least one of the plurality of discrete emitter sections provides a continuous wave beam of laser radiation when an electrical current is supplied to the series configuration.

27. The laser diode array of claim 13 wherein the plurality of discrete emitter sections provides a beam of radiation having one or more wavelengths between about 400 nm and about 2600 nm.

28. The laser diode array of claim 27 wherein the beam of radiation has a wavelength of 635 nm, 650 mn, 670 nm, 690 nm, 1208 nm, 1270 nm, 1310 nm, 1450 nm, 1550 nm, 1700 nm, 1930 nm, or 2100 nm.

29. The laser diode array of claim 13 wherein the light emitting material comprises a semiconductor material.

30. The laser diode array of claim 29 wherein the semiconductor material comprises InGaAlP, InGaP, InGaAs, InGaN, or InGaAsP.

31. The laser diode array of claim 13 wherein the substrate comprises diamond, ceramic, BeO, alumina, or a gold plated ceramic.

32. A method of preventing indium migration in a series connected, continuous wave laser diode array, comprising:
providing a light emitting material having a plurality of active regions spaced on a surface of a substrate and an inactive region encapsulating the active regions on the substrate;
removing one or more portions of the inactive region between adjacent active regions to form a plurality of discrete emitter sections in the light emitting material; and
removing one or more portions of the substrate to electrically and physically isolate each discrete emitter section from an adjacent discrete emitter section to prevent indium migration between adjacent discrete emitter sections.

33. The method of claim 32 further comprising electrically connecting the plurality of discrete emitter sections in a series configuration to form the laser diode array.
